(19) United States
(12) Patent Application Publication
(10) Pub. No.: US 2024/0178239 A1
(43) Pub. Date: May 30, 2024

(54) DISPLAY PANEL AND MANUFACTURING METHOD THEREOF, AND MOBILE TERMINAL

(71) Applicant: GUANGZHOU CHINA STAR OPTOELECTRONICS SEMICONDUCTOR DISPLAY TECHNOLOGY CO., LTD., Guangzhou, Guangdong (CN)

(72) Inventors: Bin Zhao, Guangzhou, Guangdong (CN); Hang Wang, Guangzhou, Guangdong (CN); Jun Zhao, Guangzhou, Guangdong (CN)

(73) Assignee: GUANGZHOU CHINA STAR OPTOELECTRONICS SEMICONDUCTOR DISPLAY TECHNOLOGY CO., LTD., Guangzhou, Guangdong (CN)

(21) Appl. No.: 17/758,011

(22) PCT Filed: May 10, 2022
(86) PCT No.: PCT/CN2022/091846

§ 371 Date: Jun. 26, 2022

(30) Foreign Application Priority Data
Apr. 14, 2022 (CN) 202210393792.8

(51) Int. Cl. H01L 27/12

(52) U.S. Cl. CPC H01L 27/1248; H01L 27/127

(57) ABSTRACT

The present application provides a display panel and a manufacturing method thereof, and a mobile terminal. The display panel includes a substrate, a film transistor layer, an oxygen supplement functional layer, and an electrode layer; the thin film transistor layer includes a gate electrode, a gate insulating layer, an active layer, and a source-drain electrode layer. Material of the active layer is metal oxide semiconductor; material of the electrode layer is metal oxide material. Wherein oxygen content on a side of the oxygen supplement functional layer close to the electrode layer is greater than oxygen content on a side of the oxygen supplement functional layer close to the active layer.

### FIELD OF INVENTION

The present application relates to a field of display technology, and in particular to a display panel and manufacturing method thereof, and a mobile terminal.

### BACKGROUND OF INVENTION

Oxide thin film transistors (TFTs) with advantages such as low processing temperature, high mobility, and transparency to visible light, can produce large-area high-quality thin films at room temperature, and is compatible with existing production line equipment, and can be manufactured on flexible, so they are considered to be one of the most promising next generation thin film transistors.

Generally, a thin film transistor includes a gate electrode, an active layer, a source electrode, and a drain electrode. The source electrode and the drain electrode are respectively disposed at either ends of the active layer and contact the active layer, respectively. In practical applications, the source electrode and the drain electrode are conducted through the active layer, carriers flow from the source electrode to the drain electrode or from the drain electrode to the source electrode. Wherein, the active layer is usually formed by wet etching, and the source electrode and the drain electrode are also formed by wet etching. Therefore, when manufacturing the source electrode and the drain electrode, the active layer is easily affected by etchant and generates defects (increasing oxygen vacancies), carrier transport rate is reduced due to influence of external thermal or light stimulation, so that a threshold voltage is offset positively or negatively, which affects working stability of the thin film transistor.

### SUMMARY OF INVENTION

Embodiments of the present application provide a mobile terminal to alleviate deficiencies in related art.

In order to realize above functions, technical solution provided by the embodiment of the present application is as follows:
embodiment of the present application providing a display panel, includes:
a substrate;
a thin film transistor layer disposed on the substrate, the thin film transistor layer including a gate electrode, a gate insulating layer, an active layer, and a source-drain electrode layer which are disposed on the substrate;
an oxygen supplement functional layer located on a side of the source-drain electrode layer away from the active layer;
an electrode layer located on a side of the oxygen supplement functional layer away from the thin film transistor layer, material of the electrode layer being metal oxide material;
wherein oxygen content on a side of the oxygen supplement functional layer close to the electrode layer is greater than the oxygen content on a side of the oxygen supplement functional layer close to the active layer.

In the display panel provided in the embodiment of the present application, the display panel includes a first passivation layer on a side of the thin film transistor layer away from the substrate, the oxygen supplement functional layer includes the first passivation layer; the electrode layer is one of a pixel electrode, a common electrode, or an anode.

In the display panel provided by the embodiment of the present application, the electrode layer is one of the pixel electrode or a common electrode, the display panel further includes a second passivation layer on a side of the electrode layer away from the oxygen supplement functional layer.

In the display panel provided by the embodiment of the present application, the electrode layer is an anode, the display panel further includes a pixel definition layer on the side of the electrode layer away from the oxygen supplement functional layer.

In the display panel provided by the embodiment of the present application, material of the electrode layer is indium gallium zinc oxide.

In the display panel provided by the embodiment of the present application, the inert gas is one or more mixed gases of helium, neon, argon, krypton, xenon, and radon.

An embodiment of the present application provides a method for manufacturing a display panel, steps of the manufacturing method include:
providing a substrate, forming a gate electrode, a gate insulating layer, an active layer, a source-drain electrode layer, and a first passivation layer on the substrate in sequence;
forming a metal oxide layer on the first passivation layer in an environment where gas pressure ratio of oxygen to inert gas is greater than 40%; and
etching the metal oxide layer, conducting the etched metal oxide layer to form an electrode layer, wherein oxygen content on a side of the first passivation layer close to the electrode layer is greater than the oxygen content on a side of the first passivation layer close to the active layer.

In the manufacturing method provided by the embodiment of the present application, material of the active layer is metal oxide semiconductor; material of the electrode layer is indium gallium zinc oxide.

In the manufacturing method provided by the embodiment of the present application, the step of forming the metal oxide layer on the first passivation layer in the environment where the gas pressure ratio of the oxygen to the inert gas is greater than 40% includes: forming a metal oxide film on a side of the first passivation layer away from the source-drain electrode layer;
patterning the metal oxide film to form the metal oxide layer in the environment where the gas pressure ratio of the oxygen to the inert gas is greater than 40%.

In the manufacturing method provided by the embodiment of the present application, the electrode layer is one of a pixel electrode or a common electrode, the manufacturing method further includes following step:
forming a second passivation layer on a side of the electrode layer away from the first passivation layer by a deposition process.

In the manufacturing method provided by the embodiment of the present application, the step of etching the metal oxide layer, conducting the etched metal oxide layer to form the electrode layer, wherein the oxygen content of the side of the first passivation layer close to the electrode layer is greater than the oxygen content of the side of the first passivation layer close to the active layer includes:
etching the metal oxide layer to form electrode patterns;
plasma-treating the electrode pattern so as to conduct the electrode pattern to form the pixel electrode or the common electrode.

In the manufacturing method provided by the embodiment of the present application, the electrode layer is an anode, the manufacturing method further includes the following step:
forming a pixel definition layer on a side of the electrode layer away from the oxygen supplement functional layer by a deposition process.

In the manufacturing method provided by the embodiment of the present application, the step of etching the metal oxide layer, conducting the etched metal oxide layer to form an electrode layer, wherein the oxygen content of the side of the first passivation layer close to the electrode layer is greater than the oxygen content of the side of the first passivation layer close to the active layer includes:
etching the metal oxide layer to form electrode patterns;
plasma-treating the electrode pattern so as to conduct the electrode pattern to form the anode.

In the manufacturing method provided by the embodiment of the present application, the deposition process is a plasma-enhanced vapor deposition process, the plasma includes one or more mixed gases of helium, argon, hydrogen, and oxygen.

An embodiment of the present application provides a mobile terminal, includes a terminal body and a display panel, the terminal body and the display panel are combined integrally, the display panel includes:
a substrate;
a thin film transistor layer disposed on the substrate, the thin film transistor layer including a gate electrode, a gate insulating layer, an active layer, and a source-drain electrode layer which are disposed on the substrate, material of the active layer being a metal oxide semiconductor;
an oxygen supplement functional layer located on a side of the source-drain electrode layer away from the active layer;
an electrode layer located on a side of the oxygen supplement functional layer away from the thin film transistor layer, material of the electrode layer being a metal oxide material;
wherein oxygen content on a side of the oxygen supplement functional layer close to the electrode layer is greater than the oxygen content on a side of the oxygen supplement functional layer close to the active layer.

In the mobile terminal provided in the embodiment of the present application, the display panel includes a first passivation layer on a side of the thin film transistor layer away from the substrate, the oxygen supplement functional layer includes the first passivation layer; the electrode layer is one of a pixel electrode, a common electrode, or an anode.

In the mobile terminal provided in the embodiment of the present application, the electrode layer is one of a pixel electrode or a common electrode, the display panel further includes a second passivation layer on the side of the electrode layer away from the oxygen supplement functional layer.

In the mobile terminal provided in the embodiment of the present application, the electrode layer is an anode, the display panel further includes a pixel definition layer located on the side of the electrode layer away from the oxygen supplement functional layer.

In the mobile terminal provided in the embodiment of the present application, material of the electrode layer is indium gallium zinc oxide.

In the mobile terminal provided in the embodiment of the present application, the inert gas is one or more mixed gases selected from helium, neon, argon, krypton, xenon, and radon.

The present application provides the display panel and the manufacturing method thereof, the mobile terminal. The display panel includes the thin film transistor layer, the oxygen supplement functional layer, and the electrode layer stacked on the substrate; the thin film transistor layer includes the gate electrode, the gate insulating layer, the active layer and the source-drain electrode layer which are disposed on the substrate, material of the active layer is metal oxide semiconductor, material of the electrode layer is metal oxide material, wherein, the oxygen content on the side of the oxygen-supplement functional layer close to the electrode layer is greater than the oxygen content on the side of the oxygen-supplement functional layer close to the active layer, the oxygen-supplement functional layer is used for injecting oxygen ions and releasing oxygen ions to fill oxygen vacancies in the active layer when the electrode layer is manufactured. It resolves defect in the prior art that the carrier transfer rate is reduced due to increase of oxygen vacancies in the active layer and influence of external thermal or light stimulation, threshold voltage is offset positively or negatively, which affects working stability of a device of the display panel.

### BRIEF DESCRIPTION OF DRAWINGS

Technical solutions and other beneficial effects of the present application will be apparent through detailed description of specific embodiments of the present application in conjunction with accompanying drawings.

FIG. 1 is a first schematic structural diagram of a display panel provided by an embodiment of the present application.

FIG. 2 is a flowchart of a method for manufacturing a display panel provided by an embodiment of the present application.

FIG. 3A to FIG. 3D are structural process flow diagrams for manufacturing the display panel shown in FIG. 1.

FIG. 4 is a second schematic structural diagram of the display panel provided by an embodiment of the present application.

FIG. 5 is a third schematic structural diagram of the display panel provided by an embodiment of the present application.

FIG. 6A to FIG. 6C are structural process flow diagrams of the display panel in FIG. 5.

### DETAILED DESCRIPTION OF PREFERRED EMBODIMENTS

Embodiments of the present application provide a display panel and a manufacturing method thereof, and a mobile terminal. In order to make objects, technical solutions, and effects of the present application clearer and definite, the present application will be further described below with reference to accompanying drawings and the embodiments. It should be understood that the specific embodiments described herein are only used to explain the present application, but not to limit the present application.

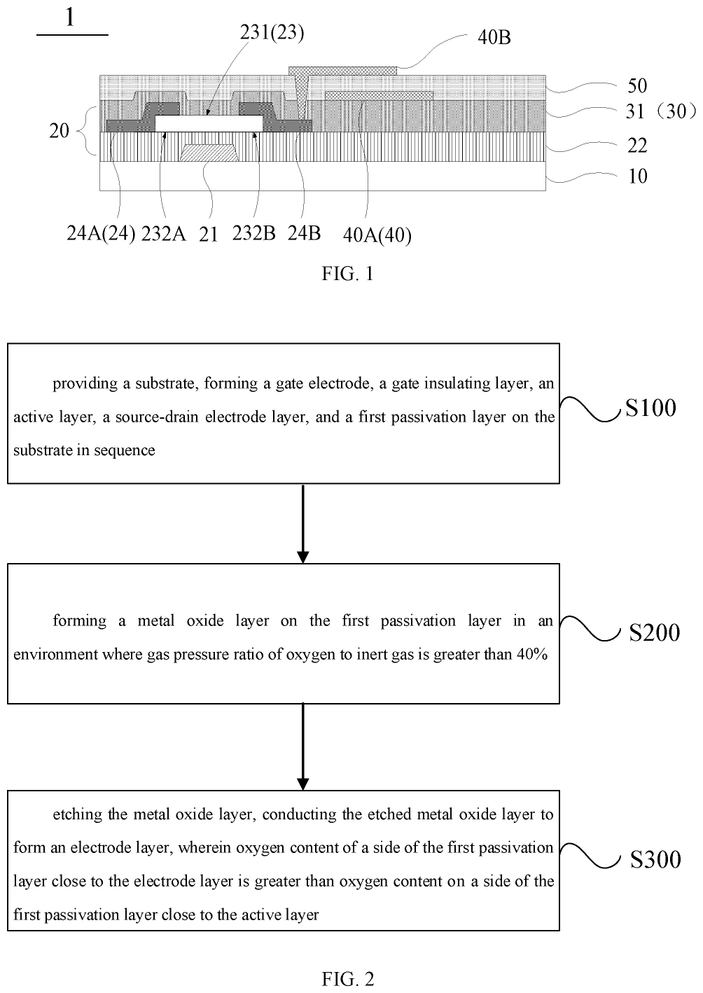

Referring to FIG. 1 to FIG. 6C, the embodiments of the present application provide a display panel and a manufacturing method thereof, and a mobile terminal. The display panel 1 includes:
a substrate 10;
a thin film transistor layer 20 disposed on the substrate 10, the thin film transistor layer 20 includes a gate electrode 21, a gate insulating layer 22, an active layer 23, and a source-drain electrode layer 24 disposed on the substrate 10, a material of the active layer 23 is a metal oxide semiconductor;
an oxygen supplement functional layer 30 located on a side of the active layer 23 away from the substrate 10;
an electrode layer 40 located on a side of the oxygen supplement functional layer 30 away from the thin film transistor layer 20, a material of the electrode layer 40 is a metal oxide material;
wherein oxygen content on a side of the oxygen supplement functional layer 30 close to the electrode layer 40 is greater than oxygen content on a side of the oxygen supplement functional layer 30 close to the active layer 23.

It can be understood that, in existing display panels, an oxide type thin film transistor (TFT) includes a gate electrode, an active layer, a source electrode, and a drain electrode. The source electrode and the drain electrode are respectively located at either ends of the active layer and contact the active layer, respectively. In practical applications, the source electrode and drain electrode electrically conduct through the active layer, carriers flow from the source electrode to the drain electrode or from the drain electrode to the source electrode. Wherein the active layer is usually formed by wet etching, and the source electrode and drain electrode are also formed by wet etching. Therefore, when the source electrode and the drain electrode are manufactured, the active layer is easily affected by etchant and generates defects (increase in oxygen vacancies). Carrier transmission rate is reduced due to influence of external thermal stimulation or light stimulation, a threshold voltage is offset positively or negatively, which affects working stability of the thin film transistor.

In the embodiment of the present application, the electrode layer 40 is disposed on the side of the oxygen supplement functional layer 30 away from the active layer 23, the electrode layer 40 contacts the oxygen supplement functional layer 30, a material of the electrode layer 40 is a metal oxide material. Wherein the oxygen content on the side of the oxygen supplement functional layer 30 close to the electrode layer 40 is greater than the oxygen content on the side of the oxygen supplement functional layer 30 close to the active layer 23. The oxygen supplement functional layer 30 is used for injecting oxygen ions and releasing oxygen ions to fill oxygen vacancies in the active layer 23 when the electrode layer 40 is manufactured. Therefore, it resolves defect in the prior art that carrier transfer rate is reduced due to increase in the oxygen vacancies in the active layer 23 and influence of external thermal stimulation or light stimulation, the threshold voltage is offset positively or negatively, which affects the working stability of device of the display panel 1.

In an embodiment, please refer to FIG. 1 and FIG. 4, FIG. 1 is a first schematic structural diagram of the display panel provided by an embodiment of the present application, FIG. 4 is a second structural schematic diagram of the display panel provided by an embodiment of the present application.

The present embodiment provides a display panel 1, the display panel 1 includes but is not limited to one of a light-emitting diode (LED) and an organic light-emitting diode (OLED) display panel 1, the present embodiment does not specifically limit it. It should be noted that the present embodiment takes the display panel as the light-emitting diode as an example to describe the technical solution of the application.

The display panel 1 includes a substrate 10, and a thin film transistor layer 20, an oxygen supplement functional layer 30, and an electrode layer 40 disposed on the substrate 10. Wherein the substrate 10 may include a rigid substrate 10 or a flexible substrate 10. When the substrate 10 is the rigid substrate 10, material may be metal or glass, when the substrate 10 is the flexible substrate 10, material may include at least one of acrylic resin, methacrylic resin, polyisoprene, vinyl resin, epoxy-based resin, polyurethane-based resin, cellulose resin, silicone resin, polyimide-based resin, or polyamide-based resin. The material of the substrate 10 is not limited in the present embodiment.

The thin film transistor layer 20 includes a gate electrode 21, an active layer 23, and a source-drain electrode layer 24 stacked on the substrate 10. The first metal layer includes the gate electrode 21 on the substrate 10. The active layer 23 includes an active segment 231 and a conductor segment connected with the active segment 231. The conductor segment includes an overlap portion (not labeled in figures) connected to the source-drain electrode layer 24. The source-drain electrode layer 24 includes a source electrode 24A and a drain electrode 24B arranged at intervals, the source electrode 24A and the drain electrode 24B are connected with the overlap portion. Specifically, the overlap portion includes a first overlap portion 232A contacting the source electrode 24A and a second overlap portion 232B contacting the drain electrode 24B, the active segment 231 is located between the first overlap portion 232A and the second overlap portion 232B. The thin film transistor layer 20 further includes a gate insulating layer 22 between the gate electrode 21 and the active layer 23, the gate electrode 21 is disposed corresponding to the active segment 231.

Further, material of the active layer 23 includes metal oxide semiconductor. The metal oxide material includes but is not limited to indium gallium zinc oxide (IGZO). Material of the first metal layer and material of the source-drain electrode layer 24 include but are not limited to at least one metal of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), and tungsten (W).

In the present embodiment, the display panel 1 further includes a first passivation layer 31 on a side of the thin film transistor layer 20 away from the substrate 10. The first passivation layer 31 contacts the active layer 23, orthographic projection of the active segment 231 on the substrate 10 is located within orthographic projection of the first passivation layer 31 on the substrate 10. Preferably, material of the first passivation layer 31 includes but is not limited to silicon oxide, silicon nitride, silicon oxynitride, etc., or a stack thereof. Specifically, in the present embodiment, the material of the first passivation layer 31 is silicon oxide (SiO). Preferably, the oxygen supplement functional layer 30 includes the first passivation layer 31.

The electrode layer 40 contacts the first passivation layer 31, material of the electrode layer 40 includes metal oxide material, the metal oxide material includes but is not limited to indium gallium zinc oxide (IGZO). It should be noted that the electrode layer 40 can be formed by manufacturing a metal oxide layer in an environment where gas pressure ratio of oxygen to inert gas is greater than 40%, etching the metal oxide layer, and conducting the etched metal oxide layer. Wherein, in process of forming the metal oxide layer, part of the oxygen ions can be injected into the first passivation layer 31. Wherein the electrode layer 40 is one of a pixel electrode or a common electrode.

Specifically, in the present embodiment, the electrode layer 40 includes a first electrode layer 40A and a second electrode layer 40B in a stacked arrangement. The first electrode layer 40A contacts the first passivation layer 31, the second electrode layer 40B is located on a side of the first electrode layer 40A away from the first passivation layer 31, the electrode layer 40 includes the first electrode layer 40A. Preferably, the first electrode layer 40A is the common electrode, the second electrode layer 40B is the pixel electrode, the second electrode layer 40B contacts the first drain electrode 24B.

It should be noted that, as shown in FIG. 4, in another embodiment, the first electrode layer 40A may be a pixel electrode, the second electrode layer 40B may be a common electrode, the first electrode layer 40A contacts the first drain electrode 24B. Therefore, the present embodiment does not specifically limit types of the first electrode layer 40A and the second electrode layer 40B.

It can be understood that, in the present embodiment, the metal oxide layer is manufactured in the environment where the gas pressure ratio of oxygen to inert gas is greater than 40%, so that part of the oxygen ions are injected into the oxygen supplement functional layer 30 during the process of forming the metal oxide layer.

Further, in the present embodiment, the display panel 1 further includes a second passivation layer 50 located between the first electrode layer 40A and the second electrode layer 40B. The second passivation layer 50 is manufactured by a deposition process, wherein the deposition process is performed in a high temperature environment, so that oxygen ions in the oxygen supplement functional layer 30 are released to the active layer 23 to fill the oxygen vacancies in the active layer 23.

It can be understood, in the present embodiment, the electrode layer 40 is disposed on the side of the oxygen supplement functional layer 30 away from the active layer 23, the electrode layer 40 contacts the oxygen supplement functional layer 30. The material of the electrode layer 40 is the metal oxide material. Wherein the oxygen supplement functional layer 30 is used for injecting oxygen ions and releasing oxygen ions to fill the oxygen vacancies in the active layer 23 when the electrode layer 40 is manufactured, so as to solve defect in the prior art that the carrier transfer rate is reduced due to the increase in the oxygen vacancies in the active layer 23 and the influence of external thermal stimulation or light stimulation, the threshold voltage is offset positively or negatively, which affects the working stability of the thin film transistor. At a same time, in the present embodiment, the first electrode layer 40A can be reused as the electrode layer 40, the first passivation layer 31 can be reused as the oxygen supplement functional layer 30. Therefore, it is not necessary to add an additional process step for preparing the oxygen supplement functional layer 30 in manufacturing the display panel 1, thereby effectively simplifying the manufacturing process of the display panel 1.

It should be noted, in the present embodiment, stacked arrangement of the gate electrode 21, the gate insulating layer 22, and the active layer 23 is only used for illustration, film structure of the thin film transistor layer 20 is not specifically limit in the present embodiment.

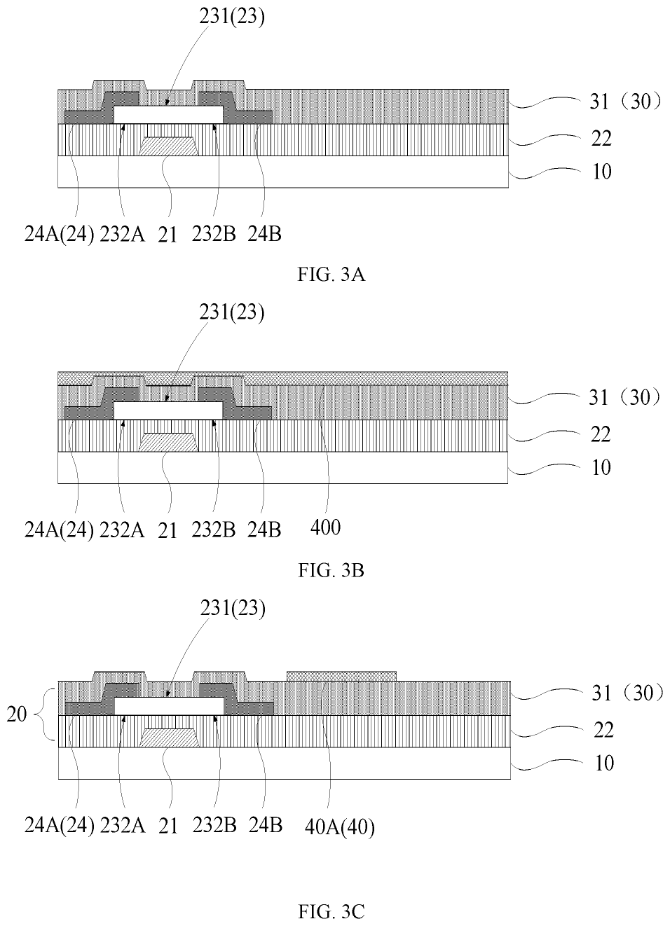

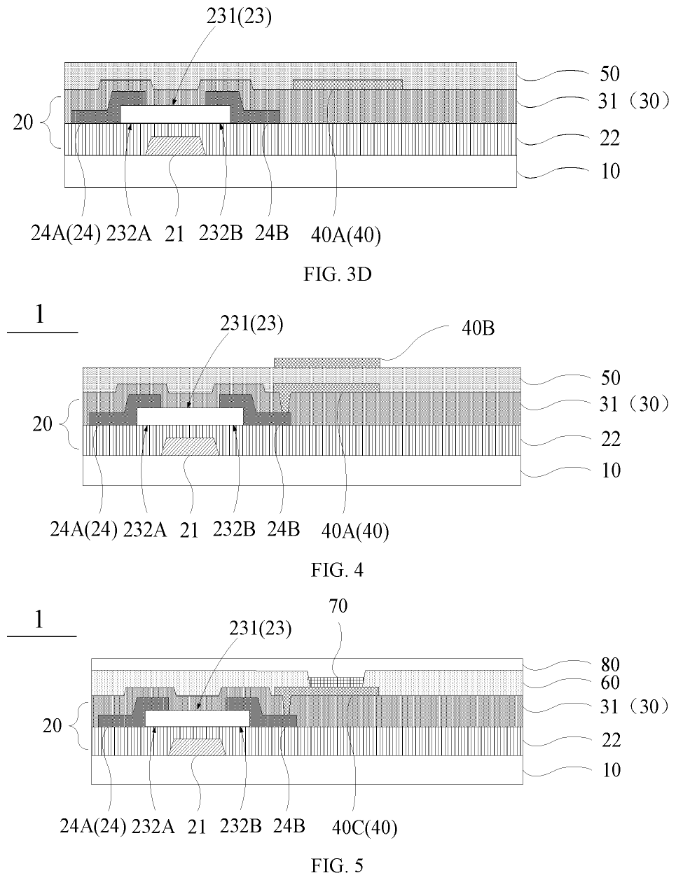

Please refer to FIG. 1, FIG. 2, FIG. 3A to FIG. 3D. FIG. 1 is a schematic diagram of the first structure of the display panel provided by an embodiment of the present application. FIG. 2 is a flowchart of the method for manufacturing the display panel provided by the embodiment of the present application. FIG. 3A to FIG. 3D are structural process flow diagrams of the display panel in FIG. 1.

The present embodiment provides the method for manufacturing the display panel 1, the steps of the manufacturing method include:

Step S100: providing a substrate 10, forming a gate electrode 21, a gate insulating layer 22, an active layer 23, a source-drain electrode layer 24, and a first passivation layer 31 on the substrate in sequence, as shown in FIG. 3A.

Specifically, the Step S100 includes following steps:

Step S101: depositing a first metal layer on the substrate 10, patterning the first metal layer to form the gate electrode 21, wherein material of the first metal layer includes but is not limited to at least one metal of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), and tungsten (W).

Step S102: forming a gate insulating layer 22 on a side of the gate electrode 21 away from the substrate 10, wherein material of the gate insulating layer 22 includes but is not limited to silicon oxide, silicon nitride, silicon oxynitride, etc., or a stack thereof.

Step S103: depositing a metal oxide film on the substrate 10, wherein material of the metal oxide film includes but is not limited to indium gallium zinc oxide (IGZO), and patterning the metal oxide film to form the active layer 23.

Step S104: depositing a source-drain electrode layer 24 on a side of the active layer 23 away from the gate insulating layer 22, patterning the first metal layer to form the source-drain electrode layer 24, wherein material of the source-drain electrode layer 24 includes but is not limited to at least one metal of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), and tungsten (W).

Specifically, the active layer 23 includes an active segment 231 and a conductor segment connected to the active segment 231. The conductor segment includes an overlap portion connected to the source-drain electrode layer 24. The source-drain electrode layer 24 includes a source electrode 24A and a drain electrode 24B arranged at intervals. The overlap portion includes a first overlap portion 232A contacting the source electrode 24A and a second overlap portion 232B contacting the drain electrode 24B. The active segment 231 is located between the first overlap portion 232A and the second overlap portion 232B.

Step S105: forming a first passivation layer 31 on a side of the source-drain electrode layer 24 away from the active layer 23. Wherein the first passivation layer 31 contacts the active segment 231, orthographic projection of the active segment 231 on the substrate 10 is located within orthographic projection of the first passivation layer 31 on the substrate 10. Preferably, material of the first passivation layer 31 includes but is not limited to silicon oxide, silicon nitride, silicon oxynitride, etc., or stacked thereof. Specifically, in the present embodiment, the material of the first passivation layer 31 is silicon oxide (SiO).

Step S200: forming a metal oxide layer 400 on the first passivation layer 31 in an environment where gas pressure ratio of oxygen to inert gas is greater than 40%, as shown in FIG. 3B.

Wherein the metal oxide layer 400 is formed by a deposition process within a production chamber, specifically, in the production chamber, the gas pressure ratio of oxygen to inert gas is greater than 40%. Thereby, the metal oxide layer 400 is manufactured in a high oxygen environment so that a part of the oxygen ions are injected into the first passivation layer 31 in a process of forming the metal oxide layer 400.

Wherein the inert gas includes but is not limited to one or more mixed gases of helium, neon, argon, krypton, xenon, and radon. Preferably, in the present embodiment, the inert gas is argon.

Step S300: etching the metal oxide layer 400 and conducting the etched metal oxide layer 400 to form an electrode layer 40, wherein oxygen content of the first passivation layer 31 close to the electrode layer 40 is greater than oxygen content of the first passivation layer 31 close to the active layer 23, as shown in FIG. 3C.

Further, in the present embodiment, Step 300 includes following steps:

Step S301: etching the metal oxide layer 400 to form an electrode pattern, wherein etching method includes but is not limited to wet etching.

Step S302: performing plasma treatment with the electrode pattern to make the electrode pattern conductive so as to form a first electrode layer 40A. The first electrode layer 40A is one of pixel electrode or common electrode. Preferably, the first electrode 40A is the common electrode.

Specifically, in the Step 302, the plasma is one or more mixed gases of helium, argon, hydrogen, and oxygen. Preferably, in the present embodiment, the plasma is argon.

It can be understood that the pixel electrode and the common electrode have relatively high requirements on electrical conductivity. Therefore, the present embodiment performs plasma treatment on the electrode layer to make the electrode layer conductive, so as to improve the conductivity of the electrode layer.

Specifically, in the present embodiment, the method for manufacturing the display panel further includes following steps:

Step S400: forming a second passivation layer 50 on a side of the first electrode 40A away from the first passivation layer 31, wherein the second passivation layer 50 is manufactured by a deposition process. Wherein, the deposition process is performed in a high temperature environment, so that oxygen ions in the first passivation layer 31 are released to the active layer 23 to fill oxygen vacancies in the active layer 23, as shown in FIG. 3D.

Wherein manufacturing method of the second passivation layer 50 adopts a plasma enhanced chemical vapor deposition process (PECVD). The PECVD process is a high temperature process, so that the first passivation layer 31 can release oxygen ions during a process of forming the second passivation layer 50. Therefore, it is not necessary to add an additional “high temperature processes” to make the first passivation layer 31 release oxygen ions, which can ensure simplification of the manufacturing process.

In the present embodiment, the method for manufacturing the display panel further includes Step 500:
a second electrode layer 40B is formed on a side of the second passivation layer 50 away from the first electrode 40A, the second electrode layer 40B is the pixel electrode, the second electrode layer 40B contacts the first drain electrode 24B.

It can be understood, in the present embodiment, the electrode layer 40 is formed on a side of the first passivation layer 31 away from the active layer 23, the electrode layer 40 contacts the oxygen supplement functional layer 30. Material of the electrode layer 40 is a metal oxide material. Wherein the electrode layer 40 is manufactured in an environment where the gas pressure ratio of oxygen to argon is greater than 40%, so that part of the oxygen ions are injected into the first passivation layer 31 during formation of the electrode layer 40. In the deposition process, the oxygen ions in the first passivation layer 31 are released to the active layer 23 to fill oxygen vacancies in the active layer 23 so as to solve defect in the prior art that the carrier transfer rate is reduced due to increase in the oxygen vacancies in the active layer 23 and under an influence of external thermal stimulation or light stimulation, a threshold voltage is offset positively or negatively, which affects working stability of a thin film transistor.

At a same time, in the present embodiment, the first electrode layer 40A can be reused as the electrode layer 40, the first passivation layer 31 can be reused as the oxygen supplement functional layer 30. Therefore, it is not necessary to add an additional process step for manufacturing the oxygen supplement functional layer 30 during manufacturing of the display panel 1, so as to effectively simplify manufacturing process of the display panel 1. In addition, the oxygen supplement functional layer 30 contacts the active segment 231, the source electrode 24A and the drain electrode 24B are located between the oxygen supplement functional layer 30 and the active layer 23, thereby preventing the oxygen supplement functional layer 30 from supplying the oxygen ions to regions of the active layer 23 other than the active segment 231, resulting in electrical abnormality of the display panel 1 device.

Please refer to FIG. 5, which is a third schematic structural diagram of the display panel provided by an embodiment of the present application.

In the present embodiment, structure of the display panel is similar/same as the first structure of the display panel provided in the above-mentioned embodiment. For details, please refer to description of the display panel in above embodiment, which will not be repeated here. Difference between the two is:

The present embodiment provides a display panel 1, the display panel 1 includes but is not limited to one of a light-emitting diode (LED) and an organic light-emitting diode display panel 1 (OLED), the present embodiment does not specifically limit it. It should be noted that, in the present embodiment, the display panel is taken as the light-emitting diode display panel as an example to describe technical solution in the embodiment of the application.

In the present embodiment, the display panel 1 includes a substrate 10, and a thin film transistor layer 20, an oxygen supplement functional layer 30, and an electrode layer 40 disposed on the substrate 10. The thin film transistor layer 20 includes a gate electrode 21, a gate insulating layer 22, an active layer 23, a source-drain electrode layer 24, and a first passivation layer 31 stacked on the substrate 10. The source-drain electrode layer 24 includes a source electrode 24A and a drain electrode 24B arranged at intervals, the oxygen supplement functional layer 30 includes the first passivation layer 31.

The display panel 1 further includes an anode 40C located on a side of the first passivation layer 31 away from the active layer 23, the anode 40C contacts the first passivation layer 31. Wherein the electrode layer 40 includes the anode 40C. Specifically, the anode 40C contacts the first passivation layer 31. Material of the anode 40C includes metal oxide material, the metal oxide material includes but is not limited to indium gallium zinc oxide (IGZO). Wherein the anode 40C is manufactured in an environment where gas pressure ratio of oxygen to inert gas is greater than 40%, so that part of oxygen ions are injected into the first passivation layer 31 during a process of forming the anode 40C. Wherein the inert gas includes but is not limited to one or more mixed gases of helium, neon, argon, krypton, xenon, and radon. Preferably, in the present embodiment, the inert gas is argon.

Further, in the present embodiment, the display panel 1 further includes a pixel definition layer 60, a light emitting layer 70, and a cathode 80 located on the anode 40C away from the first passivation layer 31. A method for manufacturing the pixel definition layer 60 adopts a plasma enhanced chemical vapor deposition process (PECVD). The PECVD process is a high temperature process. Under an environment of the high temperature process, the oxygen ions in the oxygen supplement functional layer 30 are released into the active layer 23 to fill oxygen vacancies in the active layer 23.

It should be noted that in the present embodiment, the gate electrode 21, the gate insulating layer 22, and the active layer 23 in stacked arrangement is only used for illustration, the present embodiment does not specifically limit film structure of the thin film transistor layer 20.

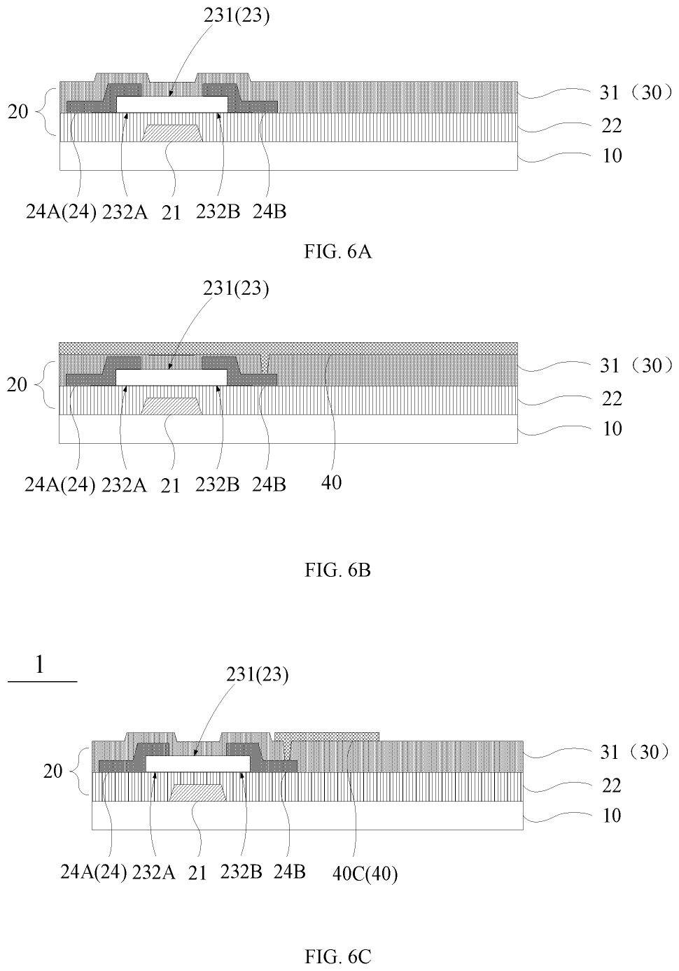

Please refer to FIG. 5 and FIG. 6A to FIG. 6C, wherein FIG. 6A to FIG. 6C are structural process flow diagrams of manufacturing the display panel in FIG. 5.

The present embodiment provides a method for manufacturing the display panel 1, which includes following steps:

Step S100: providing a substrate 10, forming a gate electrode 21, a gate insulating layer 22, an active layer 23, a source-drain electrode layer 24, and a first passivation layer 31 on the substrate 10 in sequence, as shown in FIG. 6A.

Step S200: forming a metal oxide layer 400 on the first passivation layer 31 in an environment where a gas pressure ratio of oxygen to inert gas is greater than 40%.

Further, in the present embodiment, the Step 200 includes following steps:

Step S201: forming an opening on the first passivation layer 31, the opening is located on the drain electrode 24B.

Step S202: forming the metal oxide layer 400 on the first passivation layer 31 in the environment where the gas pressure ratio of oxygen to inert gas is greater than 40%.

Material of the metal oxide layer 400 is a metal oxide material, the metal oxide material includes but is not limited to indium gallium zinc oxide (IGZO), as shown in FIG. 6B.

Wherein the metal oxide layer 400 is formed by a deposition process in a manufacturing chamber. Specifically, in the manufacturing chamber, the gas pressure ratio of oxygen to inert gas is greater than 40%, so that the metal oxide layer 400 is manufactured in a high oxygen environment, so that part of the oxygen ions are injected into the first passivation layer 31 during the process of forming the metal oxide layer 400.

Wherein the inert gas includes but is not limited to one or more mixed gases of helium, neon, argon, krypton, xenon, and radon. Preferably, in the present embodiment, the inert gas is argon.

Step S300: etching the metal oxide layer 400, conducting the etched metal oxide layer 400 to form an electrode layer 40.

Further, in the present embodiment, the Step 300 includes following steps:

Step S301: etching the metal oxide layer 400 to form an electrode pattern, wherein etching method includes but is not limited to wet etching.

Step S302: performing plasma treatment on the electrode pattern so as to conduct the electrode pattern to form an anode 40C, the anode 40C connects with the drain 24B through the opening, as shown in FIG. 6C.

Specifically, in the step 302, the plasma is one or more mixed gases of helium, argon, hydrogen, and oxygen. Preferably, in the present embodiment, the plasma is argon.

Step S400: forming a pixel definition layer 60, a light-emitting layer and a cathode in sequence on a side of the anode 40C away from the first passivation layer 31. Wherein the pixel definition layer 60 is manufactured by a deposition process. Wherein the deposition process is performed in a high temperature environment, so that the oxygen ions in the oxygen supplement functional layer 30 are released to the active layer 23 to fill the oxygen vacancies in the active layer 23, as shown in FIG. 5.

Wherein the method for manufacturing the pixel definition layer 60 adopts a plasma enhanced chemical vapor deposition process (PECVD). The PECVD process is a high temperature process, so that the oxygen supplement functional layer 30 can release the oxygen ions during the process of forming the pixel definition layer 60. It is not necessary to add an additional “high temperature process” to make the oxygen supplement functional layer 30 release oxygen ions, which can ensure simplification of the manufacturing process.

The present embodiment provides a mobile terminal, the mobile terminal includes a terminal body and the display panel described in any of the above embodiments, the terminal body and the display panel are combined integrally.

It can be understood, the display panel has been described in detail in the above embodiments, description will not be repeated here.

In specific applications, the mobile terminal may be a display screen of a device such as a smartphone, tablet computer, notebook computer, smart bracelet, smartwatch, smart glasses, smart helmet, desktop computer, smart TV, or digital camera, etc., which can even be applied to electronic devices with flexible displays.

The present application provides the display panel and the manufacturing method thereof, and the mobile terminal. The display panel includes the thin film transistor layer, the oxygen supplement functional layer, and the electrode layer stacked on the substrate; the thin film transistor layer includes the gate electrode, the gate insulating layer, the active layer and the source-drain electrode layer disposed on the substrate, the material of the active layer is the metal oxide semiconductor, the material of the electrode layer is the metal oxide material, wherein the oxygen content on the side of the oxygen supplement functional layer close to the electrode layer is greater than the oxygen content on the side of the oxygen supplement functional layer close to the active layer, the oxygen supplement functional layer is used for injecting the oxygen ions and releasing oxygen ions to fill oxygen vacancies in the active layer when the electrode layer is manufactured. It resolves defect in the prior art that the carrier transfer rate is reduced due to the increase of oxygen vacancies in the active layer and the influence of external thermal or light stimulation, the threshold voltage is offset positively or negatively, which affects the working stability of the device of the display panel.

To sum up, although the present application has disclosed the above-mentioned preferred embodiments, the above-mentioned preferred embodiments are not intended to limit the present invention. Those of ordinary skill in the art can make various changes and modifications without departing from spirit and scope of the present invention. Therefore, protection scope of the present application is subject to scope defined by claims.

What is claimed is:

1. A display panel, comprising:
a substrate;
a thin film transistor layer disposed on the substrate, the thin film transistor layer comprises a gate electrode, a gate insulating layer, an active layer, and a source-drain electrode layer disposed on the substrate, material of the active layer is metal oxide semiconductor;
an oxygen supplement functional layer located on a side of the source-drain electrode layer away from the active layer;
an electrode layer located on a side of the oxygen supplement functional layer away from the thin film transistor layer, material of the electrode layer is metal oxide material;
wherein oxygen content on a side of the oxygen supplement functional layer close to the electrode layer is greater than oxygen content on a side of the oxygen supplement functional layer close to the active layer.

2. The display panel as claimed in claim 1, wherein the display panel comprises a first passivation layer on a side of the thin film transistor layer away from the substrate, the oxygen supplement functional layer comprises the first passivation layer; the electrode layer is one of a pixel electrode, a common electrode, or an anode.

3. The display panel as claimed in claim 2, wherein the electrode layer is one of the pixel electrode or the common electrode, the display panel further comprises a second passivation layer on a side of the electrode layer away from the oxygen supplement functional layer.

4. The display panel as claimed in claim 2, wherein the electrode layer is the anode, the display panel further comprises a pixel definition layer on a side of the electrode layer away from the oxygen supplement functional layer.

5. The display panel as claimed in claim 1, wherein the material of the electrode layer is indium gallium zinc oxide.

6. (canceled)

7. A method for manufacturing a display panel, wherein steps of the method comprise:
providing a substrate, forming a gate electrode, a gate insulating layer, an active layer, a source-drain electrode layer, and a first passivation layer on the substrate in sequence;
forming a metal oxide layer on the first passivation layer in an environment where gas pressure ratio of oxygen to inert gas is greater than 40%; and
etching the metal oxide layer, conducting the etched metal oxide layer to form an electrode layer, wherein oxygen content of a side of the first passivation layer close to the electrode layer is greater than oxygen content on a side of the first passivation layer close to the active layer.

8. The method for manufacturing the display panel as claimed in claim 7, wherein material of the active layer is metal oxide semiconductor; material of the electrode layer is indium gallium zinc oxide.

9. The method for manufacturing the display panel as claimed in claim 7, wherein the step of forming the metal oxide layer on the first passivation layer in the environment where the gas pressure ratio of oxygen to inert gas is greater than 40% comprises:
forming a metal oxide film on a side of the first passivation layer away from the source-drain electrode layer;
patterning the metal oxide film to form the metal oxide layer in the environment where the gas pressure ratio of oxygen to inert gas is greater than 40%.

10. The method for manufacturing the display panel as claimed in claim 7, wherein the electrode layer is one of a pixel electrode or a common electrode, the method further comprises the following step:
forming a second passivation layer on a side of the electrode layer away from the first passivation layer by a deposition process.

11. The method for manufacturing the display panel as claimed in claim 10, wherein the step of etching the metal oxide layer, conducting the etched metal oxide layer to form the electrode layer, wherein the oxygen content of the side of the first passivation layer close to the electrode layer is greater than the oxygen content of the side of the first passivation layer close to the active layer comprises:
etching the metal oxide layer to form an electrode pattern;
plasma-treating the electrode pattern so as to conduct the electrode pattern to form the pixel electrode or the common electrode.

12. The method for manufacturing the display panel as claimed in claim 7, wherein the electrode layer is an anode, the method further comprises the following step:
forming a pixel definition layer on a side of the electrode layer away from an oxygen supplement functional layer by a deposition process.

13. The method for manufacturing the display panel as claimed in claim 12, wherein the step of etching the metal oxide layer, conducting the etched metal oxide layer to form the electrode layer, wherein the oxygen content of the side of the first passivation layer close to the electrode layer is greater than the oxygen content of the side of the first passivation layer close to the active layer comprises:
etching the metal oxide layer to form an electrode pattern;
plasma-treating the electrode pattern so as to conduct the electrode pattern to form the anode.

14. The method for manufacturing the display panel as claimed in claim 12, wherein the deposition process is a plasma-enhanced vapor deposition process, plasma in the plasma-enhanced vapor deposition process comprises one or more mixed gases of helium, argon, hydrogen, and oxygen.

15. A mobile terminal, wherein the mobile terminal comprises a terminal body and a display panel, the terminal body and the display panel are combined integrally, the display panel comprises:
a substrate;
a thin film transistor layer disposed on the substrate, the thin film transistor layer comprising a gate electrode, a gate insulating layer, an active layer, and a source-drain electrode layer disposed on the substrate, material of the active layer is metal oxide semiconductor;
an oxygen supplement functional layer located on a side of the source-drain electrode layer away from the active layer;
an electrode layer located on a side of the oxygen supplement functional layer away from the thin film transistor layer, material of the electrode layer is metal oxide material;
wherein oxygen content on a side of the oxygen supplement functional layer close to the electrode layer is greater than the oxygen content on a side of the oxygen supplement functional layer close to the active layer.

16. The mobile terminal as claimed in claim 15, wherein the display panel comprises a first passivation layer on a side of the thin film transistor layer away from the substrate, the oxygen supplement functional layer comprises the first passivation layer; the electrode layer is one of a pixel electrode, a common electrode, or an anode.

17. The mobile terminal as claimed in claim 16, wherein the electrode layer is one of the pixel electrode or the common electrode, the display panel further comprises a second passivation layer on a side of the electrode layer away from the oxygen supplement functional layer.

18. The mobile terminal as claimed in claim 16, wherein the electrode layer is the anode, the display panel further comprises a pixel definition layer on a side of the electrode layer away from the oxygen supplement functional layer.

19. The mobile terminal as claimed in claim 15, wherein the material of the electrode layer is indium gallium zinc oxide.

20. (canceled)
